(19) United States
(12) Patent Application Publication
(10) Pub. No.: US 2006/0081180 A1
(43) Pub. Date: Apr. 20, 2006

(54) Substrate processing apparatus

(76) Inventors: Hidemitsu Aoki, Kanagawa (JP); Tatsuya Suzuki, Kanagawa (JP); Yuuji Shimizu, Kanagawa (JP)

Correspondence Address: YOUNG & THOMPSON, 745 SOUTH 23RD STREET, 2ND FLOOR, ARLINGTON, VA, 22202, US

(21) Appl. No.: 11/241,996

(22) Filed: Oct. 4, 2005

(30) Foreign Application Priority Data
Oct. 4, 2004 (JP) 2004-291531

(51) Int. Cl. B05C 13/02; B05C 11/00; H01L 21/00

(52) U.S. Cl. 118/696; 118/52; 118/313; 118/50.1

(57) ABSTRACT

The invention provides a substrate processing apparatus that offers high processing efficiency in resist removal, cleaning and so on. The substrate processing apparatus includes a substrate mounting table that rotates with a semiconductor substrate retained thereon, a first container that stores a first liquid to be supplied to a surface of the semiconductor substrate, a second container that stores a second liquid to be supplied to the surface of the semiconductor substrate, a mixing unit connecting the first container and the second container, so as to mix the first liquid and the second liquid supplied from the first and the second containers thus to give a mixed solution, and a nozzle connecting the mixing unit so as to supply the mixed solution to the surface of the semiconductor substrate.

This application is based on Japanese patent application No.2004-291531, the content of which is incorporated hereinto by reference.

### BACKGROUND OF THE INVENTION

1. Field of the Invention

The present invention relates to a substrate processing apparatus that performs processings such as resist stripping, cleaning and etching, on a surface of a semiconductor substrate.

2. Description of the Related Art

A manufacturing process of semiconductor apparatuss includes frequently repeated wet processings such as cleaning, etching and resist stripping, for which chemical solutions are employed. The processing apparatuses employed for such wet processings are broadly classified into dip-type processing apparatuses and single wafer processing apparatuses. The dip-type apparatuses generally include a processing tank, in which a plurality of wafers is dipped for processing. This method provides the advantage that a plurality of wafers can be processed at a time. On the other hand, since a plurality of wafers is aligned when dipped in a processing solution, a contaminant once removed from the wafer surface may adhere again to the surface of another near-by wafer, after dissolving or dispersing in the solution. In contrast, the single wafer processing apparatuses perform the processing for each single wafer separately. The wafer is horizontally fixed on a retaining table, which rotates the wafer along its plane while the processing solution is injected on the surface of the wafer. This method can eliminate the problem of contamination from other wafers, to thereby achieve higher cleanliness during the processing.

The following passage describes an operation of an existing single wafer processing apparatus.

FIGS. 6A and 6B illustrate a configuration of a substrate cleaning apparatus disclosed in JP-A No.H06-291098. This apparatus is designed to effectively utilize the heat of mixing generated when solutions of H₂SO₄ and H₂O₂ are mixed, for promoting the reaction. More specifically, H₂SO₄ and H₂O₂ are injected through separate nozzles 7, 4, so that these solutions are mixed at a mixing point P located right under and close to the nozzles, thus to give a H₂SO₄—H₂O₂ mixed solution 8 (so called sulfuric acid hydrogen peroxide, hereinafter abbreviated as SPM). The mixed solution 8 is dropped onto a point close to the center of a rotating photomask substrate 13, and spread over the substrate by a centrifugal force. Adjusting the flow rate ratio between H₂SO₄ and H₂O₂, the height of the mixing point P and the rotation speed of the substrate allows minimizing the fluctuation in temperature of the mixed solution 8 by locations on the substrate, thereby achieving a uniform cleaning effect. The document states that, accordingly, such method is also applicable for wet stripping of a refractory chloromethylstylene-based resist material, which is typically employed for electron beam lithography.

Also, FIG. 5 in the document shows a configuration of an apparatus that drops a mixed solution of H₂SO₄ and H₂O₂ on the wafer, as a comparative example.

In the apparatus shown in FIGS. 6A and 6B of the present specification, however, since the two solutions are mixed after being injected through the nozzles, and besides the heat of mixing of the solutions, it is difficult to control the temperature of the solution that has reached the wafer surface. Coincidentally, JP-A No.H06-291098 states that the temperature distribution on the wafer surface largely depends on the height of the nozzle, and that an optimal value of the nozzle height is to be specified, in the description on FIGS. 2, 3 and relevant examples 1, 2 (paragraph 0035). Such difficulty in controlling the wafer surface temperature is a bottleneck in constantly achieving excellent processing efficiency.

In addition, the apparatus shown in FIG. 5 of the document supplies the mixed solution directly to the wafer from the mixing unit, which, as stated in the document, incurs the temperature fluctuation by locations on the wafer surface, thus impeding uniform processing of the wafer. Further, not only the temperature, but also the composition of the mixed solution supplied to the wafer is prone to fluctuate.

FIGS. 7A and 7B depict a part of a substrate cleaning apparatus disclosed in JP-A No.2000-183013. This apparatus is provided with a nozzle structure that mixes two chemical solutions before supplying the mixed solution to the wafer surface. Such nozzle structure is shown in FIGS. 7A and 7B. The nozzle structure is constituted of a nozzle unit including therein a plurality of nozzle tips, so that two chemical solutions are mixed inside the nozzle unit. Referring to FIG. 7B, the nozzle unit 13 is divided into a nozzle tip 15 for a chemical solution A 14, a nozzle tip 17 for a chemical solution B 16, and a nozzle tip 19 for pure water 18. The nozzle tips are respectively connected to a container containing the chemical solution A 14, the chemical solution B 16 and pure water 18 via a piping, for cleaning the wafer.

Further, a technique of heating a substrate when cleaning or otherwise processing the substrate is disclosed in JP-A No.2002-118085. This document proposes heating the substrate to be processed up to 30 degree centigrade or higher, when performing the processing.

The conventional techniques disclosed in the foregoing documents, however, do not always provide sufficient processing efficiency in removing the resist or cleaning the substrate. For example, when stripping a refractory resist pattern or cleaning a substrate on which such resist has been used, often the resist cannot be completely removed, and hence residue of the resist remains on the wafer.

### SUMMARY OF THE INVENTION

According to the present invention, there is provided a substrate processing apparatus, comprising:

a substrate mounting table that rotates with a semiconductor substrate retained thereon,

a first container that stores a first liquid to be supplied to a surface of the semiconductor substrate,

a second container that stores a second liquid to be supplied to the surface of the semiconductor substrate,

a mixing unit connecting the first container and the second container, so as to mix the first liquid and the second liquid supplied from the first and the second containers thus to give a mixed solution,

a nozzle that supplies the mixed solution to the surface of the semiconductor substrate,

a piping connected to the mixing unit and to the nozzle, so as to conduct the mixed solution from the mixing unit to the nozzle, and

a piping heater that heats the piping.

In the apparatus thus constructed, the first and the second liquids are mixed in advance in the mixing unit, and the mixed solution thus produced passes through the heated piping to be supplied through the nozzle to the surface of the semiconductor substrate. Since the two liquids are mixed in advance in the mixing unit, the heat of mixing as well as the chemical species given upon mixing can be effectively utilized. Also, since the mixing unit and the nozzle are connected via the piping, which is heated by the piping heater, the temperature and composition of the mixed solution can be stabilized, unlike the technique described in the patented document 1, wherein the mixed solution is directly supplied to the wafer.

According to the present invention, it is preferable that the piping heater heats an entirety of the piping, from the connection point with the mixing unit to the connection point with the nozzle.

According to the present invention, it is preferable that the mixing unit is of a tightly closed structure isolated from an external region of the apparatus.

The substrate processing apparatus may include a plurality of nozzles that communicates with the mixing unit. For example, the substrate processing apparatus may include a first nozzle that supplies the mixed solution to a central portion of the semiconductor substrate, and a second nozzle that supplies the mixed solution to a peripheral portion of the semiconductor substrate.

The substrate processing apparatus may include a heater that heats the mixing unit. Also, the substrate processing apparatus may include a nozzle heater that heats the nozzle.

The substrate processing apparatus may further include a controller that controls a rotating speed of the substrate mounting table, such that the controller causes the semiconductor substrate to rotate at a relatively higher speed in an initial stage of the processing, and to rotate at a relatively lower speed in a latter stage of the processing.

Inside the mixing unit, the first liquid and the second liquid may be caused to spirally move along an inner wall of the mixing unit, thus to be mixed. The mixing unit may include a hollow spiral tube. Under such structure, the heater may be a tubular heater through which a heat medium passes, and the spiral tube may be disposed inside the tubular heater.

The substrate processing apparatus may further include a moving unit that moves at least one of the nozzles.

The mixed solution may be a substrate cleaning solution. For example, the first liquid may contain sulfuric acid, and the second liquid may contain hydrogen peroxide. When such solutions are employed as the first and the second liquids, the process may be followed by a rinse process in which an alkaline solution or alkali-reduced water, and further by a pure water rinse process.

According to the present invention, since the first and the second liquids are mixed in advance in the mixing unit, and the mixed solution thus produced is supplied through the nozzle to the semiconductor substrate surface, the processing can be efficiently performed effectively utilizing the heat of mixing.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a configuration of a substrate processing apparatus according to an embodiment of the present invention;

FIG. 2 is a schematic side view showing a structure of a substrate mounting table;

FIG. 3 is a perspective view showing a structure of a mixing unit;

FIG. 4 is a block diagram showing a configuration of a substrate processing apparatus according to another embodiment of the present invention;

FIGS. 5A and 5B are schematic drawings for explaining positional relationship between a nozzle and a semiconductor substrate;

FIGS. 6A and 6B are schematic side views showing a configuration of a conventional substrate processing apparatus;

FIGS. 7A and 7B are schematic side views showing a part of the conventional substrate processing apparatus;

FIG. 8 is a block diagram showing a configuration of a substrate processing apparatus according to still another embodiment of the present invention;

FIG. 9 is an enlarged side view showing a portion including the mixing unit, the piping and the nozzle; and

FIG. 10 is a perspective view showing a structure of another mixing unit.

### DETAILED DESCRIPTION OF THE INVENTION

The present invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

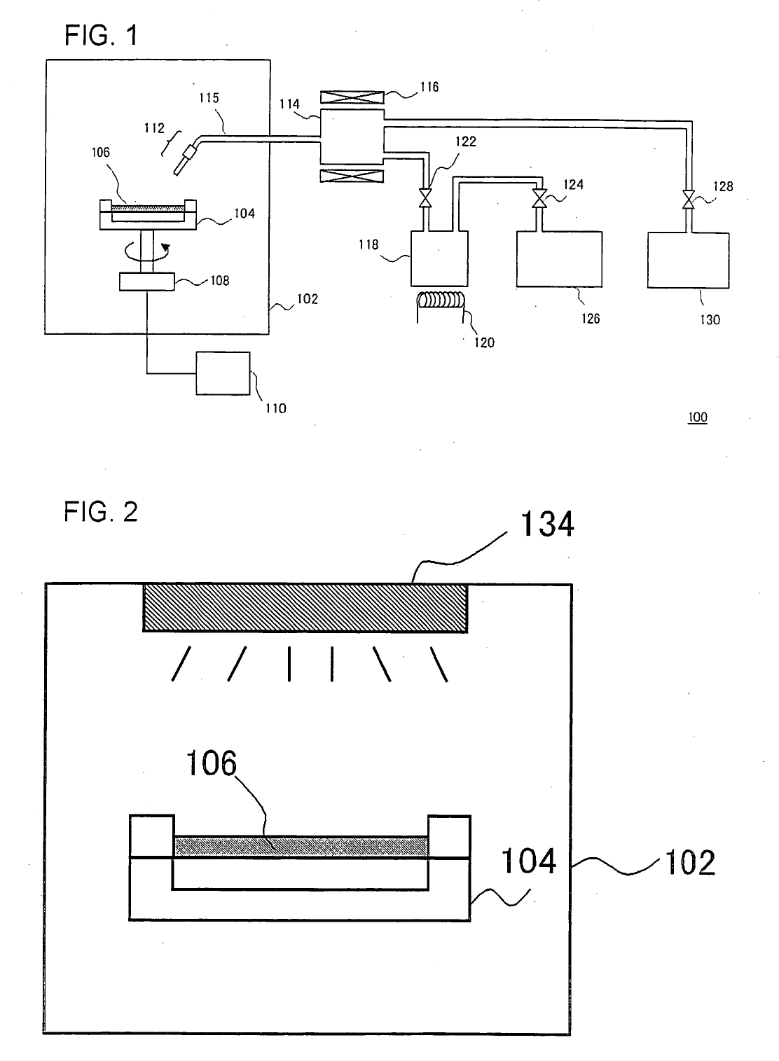

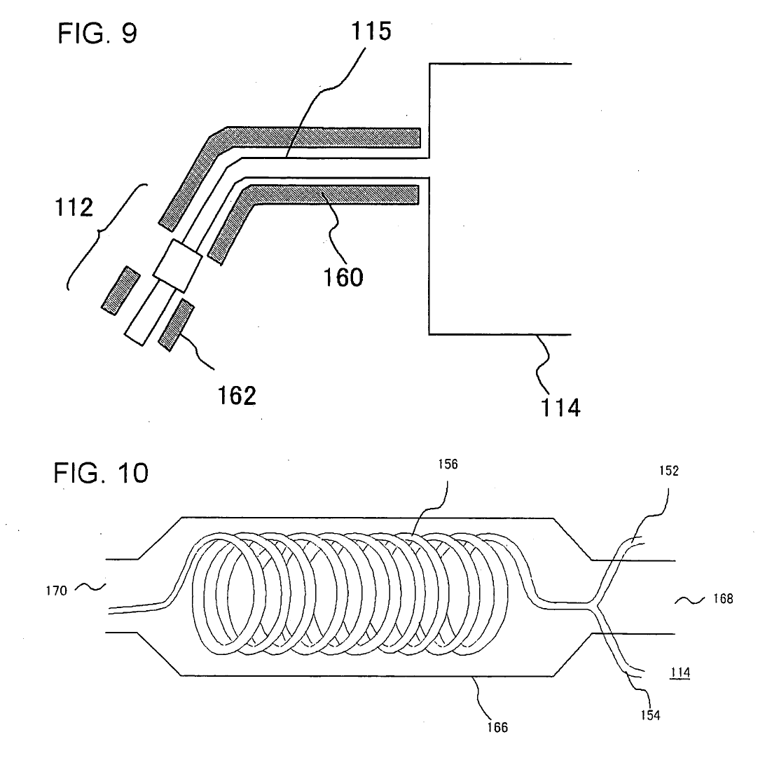

FIG. 1 is a view showing outline constitution of a substrate processing apparatus 100 according to the present embodiment. This substrate processing apparatus 100 is provided with a processing chamber 102 including a substrate mounting table 104, a first container 126 accommodating a first liquid supplied to the surface of the semiconductor substrate 106, a second container 130 accommodating a second liquid supplied to the semiconductor substrate 106, a mixing unit 114, which is communicated with the first container 126 and the second container 130, producing mixture while mixing the first and the second liquids supplied from these containers, a nozzle 112, which communicates with a mixing unit 114, supplying the mixture to surface of the semiconductor substrate 106, and a piping 115, which connect the mixing unit 114 with the nozzle 112, introducing the mixture from the mixing unit 114 to the nozzle 112. In periphery of the piping 115, piping heater 160 heating the piping 115 is disposed (FIG. 9).

A substrate mounting table 104 maintains the semiconductor substrate 106 to become objects to be treated. The substrate mounting table 104, which is connected to a motor 108, is constituted in such a way as to rotate with the condition where the semiconductor substrate 106 is made to maintain horizontally. The semiconductor substrate 106 rotates with an axis passing through the center of the substrate, and perpendicular to the surface of the substrate as axis. It may preferable that there is provided a heating part on the substrate mounting table 104 or its periphery, so that the semiconductor substrate 106 is heat insulated by the heater into predetermined temperature. FIG. 2 is a view showing an example of such constitution. In the constitution in FIG. 2, an infrared heater 134 is disposed above the substrate mounting table 104, owing to this, the surface of the semiconductor substrate 106 is heated.

A rotation controller 110 controls rotation speed of the motor 108. According to consideration of the inventor, it has become clear that, during the period of treating process, in some cases, processing efficiency is improved upon causing the number of revolution of the substrate to vary appropriately. For instance, in the resist stripping processing carried out in the present embodiment, it has become clear that resist stripping efficiency is sharply improved in a condition where, initially, the substrate rotates relatively high rotational speed, after that, the substrate rotates relatively low rotational speed.

Its reason is not necessarily apparent, however, it is guessed below. When performing impurity implantation of high dose-rate, formed on the surface of the resist is hardening layer. Such hardening layer is, generally, difficult to remove. Accordingly, increased is chance where surface of the semiconductor substrate 106 comes into contact with fresh chemical liquid upon high speed revolution of the substrate; so that it is possible to activate removal of the hardening layer, accordingly stripping processing efficiency is improved. On the contrary, after being stripped hardening layer, the substrate is not necessarily made such high speed revolution, but it is preferable that the substrate is made to rotate in low speed revolution to cause retention time of liquid on the surface of the substrate to be long time, so that it leads to reduction of quantity consumed of chemical liquid. The rotation controller 110 is capable of realizing rotational speed profile depending on processing content described above. Although there is no particular limitation in control system by the rotation controller 110, for instance, it is possible to use system driving a motor 108 based on a table, while maintaining a table in which time is made to correspond to the number of revolution.

The first container 126 and the thermal insulator 118 accommodate the first liquid used for processing. In the present embodiment, used as the first liquid is sulfuric acid. Sent for the thermal insulator 118 by a punp not shown in the drawings is the first liquid accommodated in the first container 126. Its liquid amount is adjusted by a control valve 124. The heater 120 is formed at periphery of the thermal insulator 118, thus the first liquid sent from the first container 126 is thermally insulated into predetermined temperature. In the present embodiment, the predetermined temperature is 80 to 100° C. The first liquid accommodated in the thermal insulator 118 is sent to the mixing unit 114 while being adjusted its feeding amount by the control valve 124.

The second container 130 accommodates the second liquid used for the processing. In the present embodiment, used as the second liquid is oxygenated water. The second container 130 is maintained to room temperature (20 to 30° C.); and the second liquid is directly supplied to the mixing unit 114 from the second container 130. Feeding amount of the second liquid is adjusted by the control valve 128.

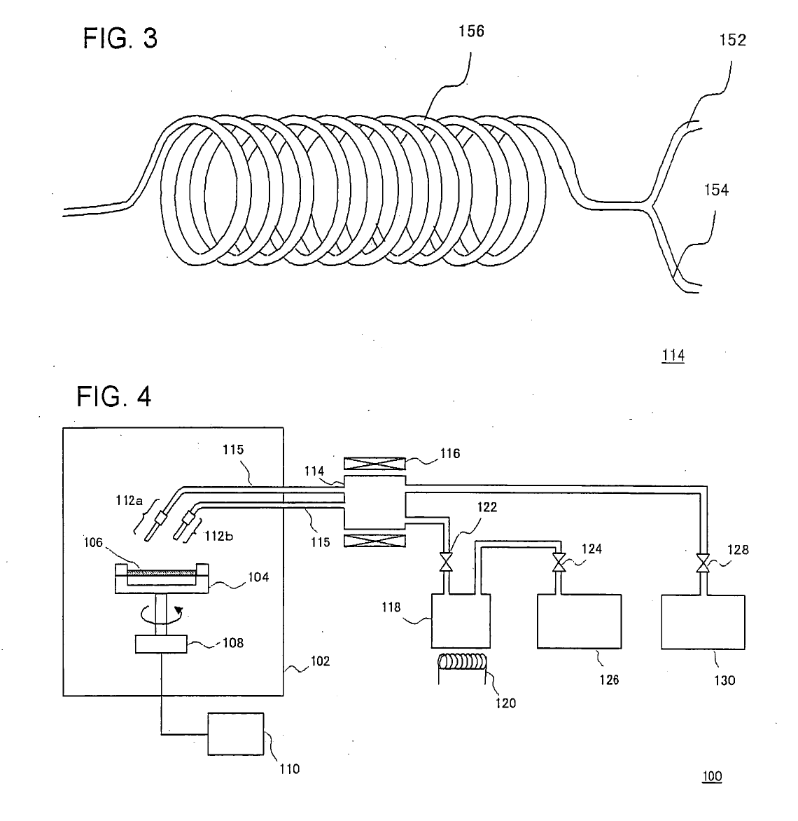

The mixing unit 114 mixes the first liquid supplied from the thermal insulator 118 with the second liquid supplied from the second container 130. As mixing systems, it is possible to use various forms. FIG. 3 is a view showing one example of constitution of the mixing unit 114. As shown in the drawings, the mixing unit 114 is provided with a piping 156 composed of a spiral tube of hollow structure, and a first inlet 152 and a second inlet 154 respectively introducing the first liquid and the second liquid to the piping 156.

By using the mixing unit 114 with such constitution, the first and the second liquids are efficiently mixed with spirally moving along an inner wall of the mixing unit. FIG. 10 shows another constitution example of the mixing unit 114. In this example, at periphery of the piping 156 to be identical with FIG. 3, tubular heater 166 is disposed. The piping 156 is disposed on the inside part of the tubular heater 166. The tubular heater 166 has an inlet 170 and an outlet 168 for warm water, and heat medium circulates in the inside part thereof. For instance, glass is taken as composition material of the tubular heater 166.

In the present embodiment, the first and the second liquids, that is, the sulfuric acid and the oxygenated water are mixed, resulting in generation of reaction heat, so that temperature of the mixture becomes not less than 100° C.; and processing efficiency is enhanced upon supplying such mixture with high temperature to the semiconductor substrate 106. However, during a period when the supply of mixture for the semiconductor substrate 106 is stopped, the mixing unit 114 is cooled, so it is conceivable that temperature of a liquid remaining inside decreases. Consequently, in the apparatus of FIG. 1, there is provided the heater 116 around the mixing unit 114 to suppress cool down of the remaining liquid.

The nozzle 112 supplies the mixture created at the mixing unit 114 to the surface of the semiconductor substrate 106. The mixture sent from the mixing unit 114 is introduced to the nozzle 112 via the piping 115. The nozzle 112 sprays mixture toward predetermined portion of the semiconductor substrate 106.

FIG. 9 is an enlarged view of part including the mixing unit 114, the piping 115 and the nozzle 112. The nozzle 112 supplies the mixture, which has become high temperature due to reaction heat, to the semiconductor substrate 106. In this respect, processing efficiency for the semiconductor substrate 106 enhanced, however, it is conceivable that, during the period when supply of the mixture for the semiconductor substrate 106 is stopped, temperature of a liquid remaining inside of the nozzle 112 decreases. Consequently, as shown in FIG. 9, in the present embodiment, the heater 162 is arranged around the nozzle 112 to suppress cool down of the remaining liquid.

Further, the piping heater 160 is arranged around the piping 115. Owing to this, during a period the mixture is fed from the mixing unit 114 to the nozzle 112, the mixture is maintained in high temperature, so that it is possible to make temperature or composition of the mixture stable.

Next, there will be described processing process of the substrate using the above apparatus.

In the present embodiment, executed is the process composed of following steps.
(i) A resist is formed on the silicon.
(ii) Patterning process of the resist is carried out.
(iii) An ion implantation is carried out with the resist as a mask. In the present embodiment, provided that, ion species: As, injection concentration: 5×10¹⁴ cm⁻².
(iv) The resist is stripped with the mixture (SPM) of sulfuric acid and oxygenated water.

In the above step (iv), used is the apparatus indicated in FIG. 1 or the like. Before carrying out (iv), the second container 130 should be prepared in a condition that inside thereof is filled with oxygen water, and the first container 126 should be prepared in a condition that inside thereof is filled with sulfuric acid. Predetermined amount of the sulfuric acid is made to introduce to the thermal insulator 118 from the first container 126, to be subjected to thermally insulating by the heater 120 at 80 to 110° C. The circumstance is maintained in this condition and preparation is performed, thereafter, processing is started. First, flow rate of the first liquid is adjusted by the control valve 122, followed by adjusting flow rate of the second liquid by the control valve 128, to introduce these liquids to the mixing unit 114. Within the mixing unit 114, these are mixed to become SPM. The mixture, which reaches liquid temperature of 100 to 120° C. due to exothermic reaction by mixing, is made to introduce onto the surface of the semiconductor substrate 106.

The number of revolution of the semiconductor substrate 106 in the processing is controlled in such a way as following conditions.
(a) Up to 15 seconds elapsed from start: 500 revolutions per minute
(b) From 15 seconds elapsed to 40 seconds elapsed: 15 revolutions per minute

Due to above (a), stripped efficiently is resist hardening layer generated by high concentration dose-rate. Next, due to above (b), removed is the resist residing on lower part than the hardening layer.

The apparatus according to the present embodiment adopts a system in which the first and the second liquids are mixed in the mixing unit 114, the mixture (SPM) is made high temperature while utilizing the heat generated at the time of the above mixing, and the mixture with high temperature is made to spray on the semiconductor substrate 106.

Liquid temperature is made to increase while utilizing reaction heat by mixing immediately before spraying to the semiconductor substrate 106, therefore, it is not necessary to provide extra mechanism for heating, so that processing liquid can be made high temperature with simple structure, and it is possible to improve processing efficiency.

Further, in the present embodiment, the part of the downstream side (semiconductor substrate 106 side) from the mixing unit 114 is subjected to thermally insulated by the heater and kept at an appropriate temperature. For this reason, the mixture with increased temperature due to reaction heat becomes possible to supply to the semiconductor substrate 106 without substantially lowering the temperature. Owing to this, it is possible to stably realize preferred processing efficiency.

Further, the apparatus according to the present embodiment adopts processing of a single-wafer system treating the wafer one-by-one using processing liquid, not the dip system dipping many wafers into the same processing liquid. In the dip system, contaminants removed from the wafer surface are dissolved or dispersed in the solution, thereafter, the problem that the contaminants re-adhere to the reverse side of another neighboring wafer easily takes place. In this respect, the present embodiment performs processing of the single-wafer system, therefore, such problem does not take place, so that it is possible to realize cleanliness with higher level.

Further, in the present embodiment, there is adopted constitution in which liquid is sprayed from the nozzle 112 after the first and the second liquids are mixed previously in the mixing unit 114. By mixing of two liquids in the inside of the mixing unit 114 of airtight structure, Caro's acid (peroxosulfate H₂SO₅) is generated, and the mixture including fixed amount of the Caro's acid is sprayed to the semiconductor substrate 106 from the nozzle 112, therefore, it is conceivable that preferred resist stripping efficiency is obtained. Although the condition that the Caro's acid is easily generated is not necessarily clear, it is conceivable that, in the case where two liquids are made to mix in the mixing unit 114 of the airtight structure as the present embodiment, there is tendency that the Caro's acid is stably generated. As later described in paragraph of Example, in the mixing of two liquids after discharging to outside from the nozzle, it is difficult to obtain stable resist stripping efficiency, thus it is desirable to provide a mixing unit of airtight structure as the present embodiment.

Further, in the present embodiment, the sulfuric acid and the oxygenated water are mixed once within airtight space, followed by further heating by the heater 116, while maintaining the Caro's acid (oxide species) generated by mixing into SPM liquid. Owing to this, it is possible to stably improve resist stripping efficiency.

### Second Embodiment

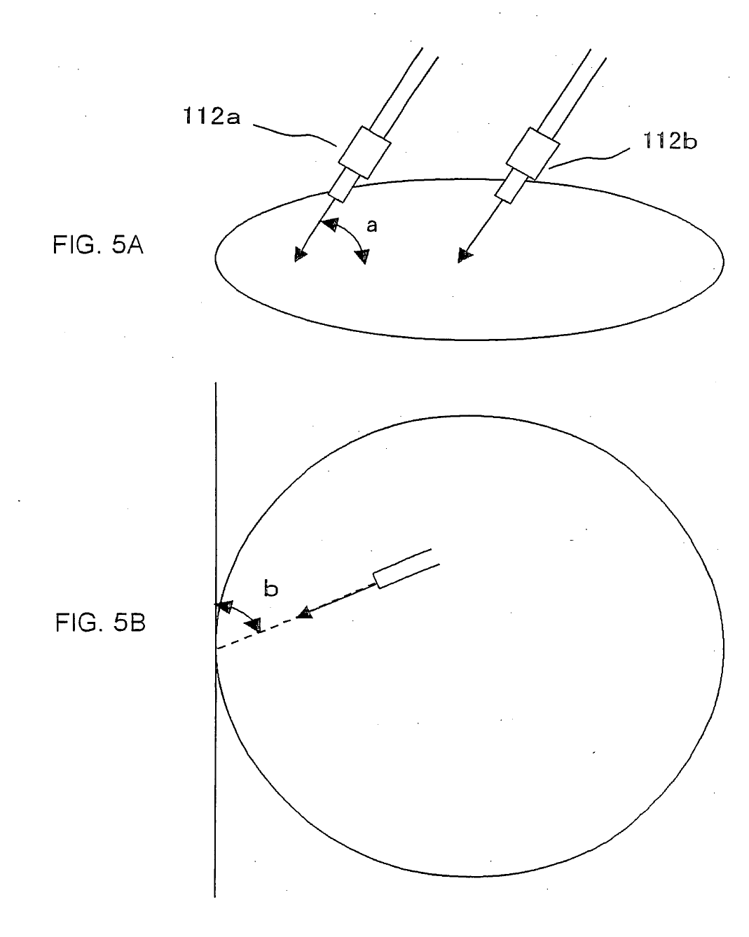

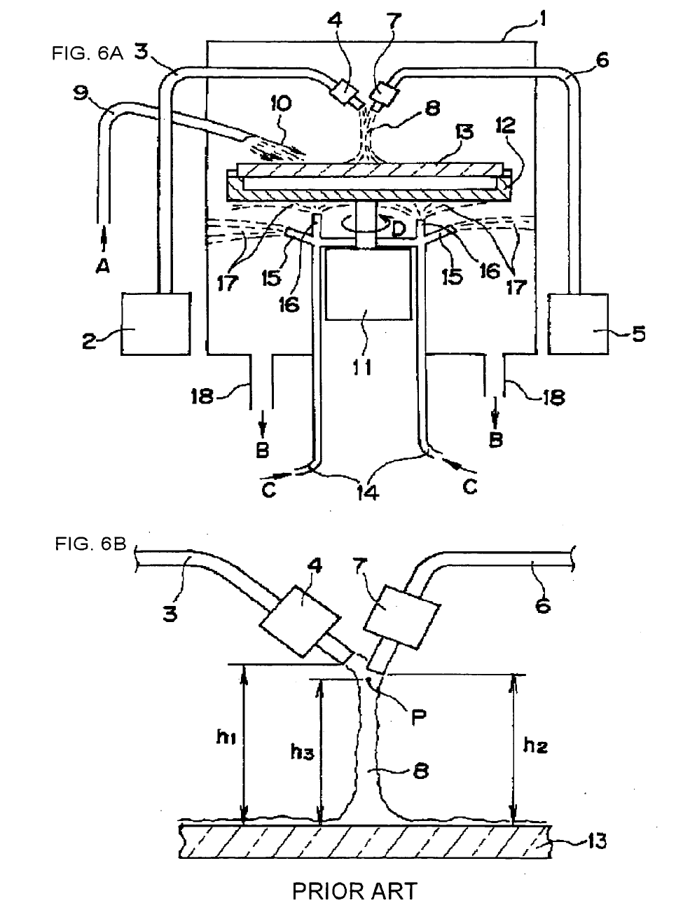

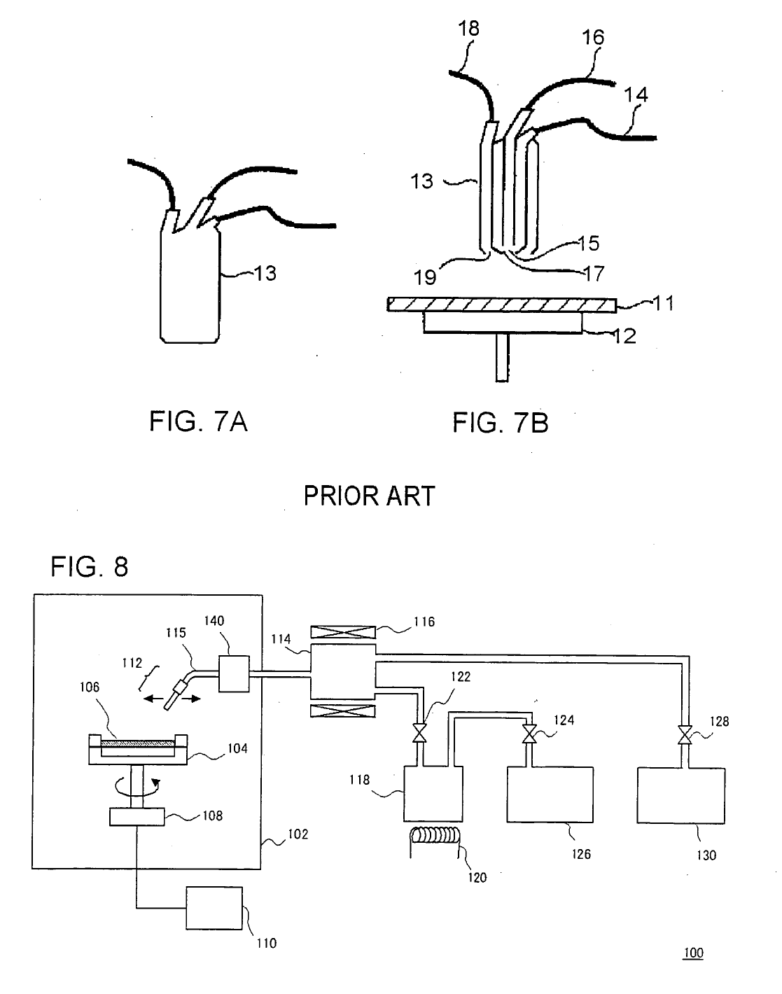

The present embodiment shows an example providing two nozzles spraying mixture to the semiconductor substrate 106. FIG. 4 is a view showing one example of the substrate processing apparatus 100 according to the present embodiment, and FIGS. 5A, 5B are views showing position relationship between nozzles 112a, 112b shown in FIG. 4 and the semiconductor substrate 106. Apparatus structure of the present embodiment is the same as the apparatus structure indicated in the first embodiment other than the nozzle structure. The point arranging the heater around the piping 115 and the nozzles 112 is the same as that indicated in the first embodiment.

As shown in FIGS. 5A, 5B the nozzle 112a sprays the mixture to the peripheral portion (end part) of the semiconductor substrate 106, and the nozzle 112b sprays the mixture to the central portion of the semiconductor substrate 106. The nozzles are prepared at the angle “a” to the substrate surface and at the angle “b” to the direction of the substrate tangent.

In the present embodiment, in addition to the effect described in the first embodiment, following effect is demonstrated.

The apparatus according to the present embodiment is provided with two nozzles of the nozzle 112a and the nozzle 112b. The constitution is that one sprays the processing liquid to the center part of the semiconductor substrate 106 and the other sprays the processing liquid to the end part of the semiconductor substrate 106. The constitution can achieve a uniform temperature distribution in a main surface of the semiconductor substrate 106, leading to a uniform resist stripping efficiency in the surface. Although the present embodiment is one in which the processing liquid is made high temperature while utilizing heat generated by mixing of two liquids, in such a case, in the surface of the semiconductor substrate 106, difference of temperature distribution easily takes place between a place to which the liquid strikes directly, and a place to which the liquid does not strike. Consequently, it is possible to improve stability of the processing in such a way that plural nozzles are made prepared as above, followed by constituting the method so as to strike the liquid to different positions of the semiconductor substrate 106.

### Third Embodiment

In the present embodiment, indicated is an example in which the mixture is made to spray to the semiconductor substrate 106. FIG. 8 is a view showing one example of the substrate processing apparatus 100 according to the present embodiment. Apparatus structure of the present embodiment is the same as the apparatus structure indicated in the first embodiment other than the nozzle structure. The point arranging the heater around the piping 115 and the nozzles 112 shown in FIG. 9 is the same as that indicated in the first embodiment. As shown in the drawing, in this apparatus, the nozzle 112 becomes movable because of control of a moving unit 140. The nozzle 112 is constituted so as to spray the mixture while moving a sprayed portion from substrate center to periphery part. In such a constitution as above, within processing surface of the semiconductor substrate 106, a uniform temperature distribution is achieved, leading to a uniform resist stripping efficiency.

Although the present embodiment is one in which the processing liquid is made high temperature while utilizing heat generated by mixing of two liquids, in such a case, in the surface of the semiconductor substrate 106, difference of temperature distribution easily takes place between a place to which the liquid strikes directly, and a place to which the liquid does not strike. Consequently, as described above, the processing is made to carry out while moving sprayed potion of the liquid, owing to this, it is possible to improve stability of the processing.

### Fourth Embodiment

Performed is a rinse process by the method of following two systems, while using the apparatus indicated in the above embodiment, after carrying out resist peeling processing by SPM.
(i) Pure water rinse processing
(ii) Pure water rinse processing, after rinsing by means of dilution ammonia water

Rinse processing by the system (ii) to completion takes shorter time than rinse processing by the system (i) to completion.

It should be noted that there has been obtained the same tendency as that also dilution APM (ammonia hydrogen peroxide water) or alkali reduced water is used instead of the system (ii).

As above, there is described the preferred embodiment of the present invention, while taking example of processing stripping the resist.

Here, particularly, resist remaining has a tendency to be easily generated at the peripheral end of the wafer. As its reason, following matter is guessed.

The first reason is that difference of temperature distribution easily takes place within wafer surface. Peripheral end of the wafer easily changes into low temperature in comparison with the center part of the wafer, as a result, it is conceivable that, in the peripheral end of the wafer, resist stripping efficiency deteriorates.

The second reason is that the resist hardening layer firmly adheres to the peripheral end of the wafer. Generally, resist is formed such that film thickness is thinning gradually from the center part of the wafer toward the peripheral end. That is, film thickness of the resist is formed in such a way as to be thick in the center part and thin in the peripheral end. In the center part of the wafer, upper part of the resist becomes the resist hardening layer, when the resist hardening layer is stripped, resist of its lower part is easily stripped by lift-off action. On the other hand, in the peripheral end of the wafer, thickness of the resist is thin, therefore, approximately whole resist deteriorates to the hardening layer, consequently, it can not be expected that the resist is stripped caused by lift-off action as the center part of the wafer. For that reason, compared with the center part of the wafer, in the peripheral end of the wafer, removal of the resist hardening layer becomes difficult.

The third reason is that the processing liquid is difficult to be maintained on the surface of the peripheral end of the wafer. In the peripheral end of the wafer, slip of the processing liquid is easy to take place, as a result, processing efficiency deteriorates.

In this respect, in the present embodiment, following measures are taken, to effectively resolve the resist remaining at the peripheral end of the wafer.

As a measure to the matter described in the above first reason, in the embodiment, upon providing the mixing unit 114, and the mixture (SPM) is prepared immediately before supplying to the semiconductor substrate 106 to control temperature. For this reason, it is possible to make temperature distribution within the surface of the wafer even. If adopting constitution provided with a plurality of nozzles 112 as the second embodiment, or constitution provided with a movable nozzle as the third embodiment, evenness of the temperature further improves.

Further, with respect to the matters described in the above second and the third reasons, in the above embodiment, the rotation controller 110 appropriately controls the number of revolution of the substrate, owing to this, the slip of processing liquid in the peripheral end of the wafer is made to suppress and stripping efficiency of the resist hardening layer is made to enhance. For instance, after treating with relatively high speed revolution, carried out is the processing with low speed revolution where the slip of the processing liquid is difficult to take place and the processing liquid is easy to be maintained at the peripheral end of the wafer.

For these reasons, in the embodiment, the resist remaining at the peripheral end of the wafer is made to effectively solve.

As above, there has been described the embodiment of the present invention with reference to the drawings, however, these are illustrations of the present invention, consequently, it is possible to adopt various constitutions other than the above descriptions.

For instance, in the above described embodiments, the SPM is used as the processing liquid, if matter is capable of sufficiently stripping the resist pattern after dry etching with the single-wafer system processing, it is possible to use the matter other than the SPM. As the resist stripping liquid described above, for instance, a solvent mainly comprising phenol and halogen-based solvent, amine-based solvent, and ketone-based solvent such as cyclopentanone or methyl ethyl ketone are indicated. Provided the resist after dry etching is modified in connection with its surface, so that, generally, solubility to the solvent is low in comparison with the resist before dry etching, and the resist residue is easy to remain, consequently, it is preferable to perform SPM cleaning with high resist peeling effect. The composition of SPM can be set to be the sulfuric acid: 30 mass % oxygenated water=1:1 to 8:1 (volume factor), and the working temperature is capable of being set within the range of 100 to 150° C. By this measure, preferable stripping performance and cleaning efficiency can be obtained stably.

Further, in the above embodiment, which takes processing of the silicon substrate as an example, however, various semiconductor substrates such as semiconductor and the like including elements of Si, Ge or the like are possible to be made application objects. Among them, in the case where the semiconductor substrate is taken to as silicon wafer, effect of the present invention is further remarkably exhibited.

In the above embodiments, stripping processing of the resist is taken to as an example, however, “processing” in the present invention includes the whole processing of substrate surface using chemical liquid or its vapor. For instance, included is wet etching processing, removing etching residue processing, or the like.

### Example 1

A resist was provided on a silicon substrate, and an opening was formed on the resist in a predetermined pattern. Then ion implantation was performed on the silicon substrate utilizing such resist as a mask. Arsenic (hereinafter, As) was employed as the ion to be implanted, and the implantation density was set at 5×10¹⁴ cm⁻². The resist employed was of a type used for a krypton fluoride (KrF) laser.

The silicon substrate was then placed on the apparatus according to the second embodiment shown in FIG. 4, at a position corresponding to the semiconductor substrate 106, and a mixed solution of sulfuric acid and hydrogen peroxide (SPM) was supplied for stripping the resist. The heaters were provided for the nozzle 112, the entire piping 115 and the mixing unit 114. The processing conditions were set as follows.

SPM composition: sulfuric acid/30wt % hydrogen peroxide=4/1 (in volume)

SPM injection amount on the wafer surface: 100 to 200 ml

Nozzle heating temperature: 100 degree centigrade

SPM processing time: 2 minutes

### Example 2

The resist stripping process was performed under similar conditions to those of the example 1, except for the following alteration of the processing conditions.

SPM composition: sulfuric acid/30wt % hydrogen peroxide=2/1 (in volume)

### Comparative Example 1

The resist stripping process was performed on a dip-type processing apparatus instead of the single wafer processing apparatus. The SPM composition was similarly set to the example 1.

The resist removal performance was evaluated with respect to the examples 1, 2 and the comparative example 1. Specifically, a wafer defect inspector was employed for measurement of the number of particles that were stuck to the surface of the processed wafers. The results are shown in Table 1.

TABLE 1

| | Number of particles |
|---|---|
| Example 1 | 5 |
| Example 2 | 240 |
| Comparative example 1 | 2540 |

### Comparative Example 2

The apparatus used for the example 1, but without the heater provided around the piping 115, was employed for performing the resist stripping process. The heaters were only provided for the nozzle 112 and the mixing unit 114. The SPM composition was similarly set to the example 1. A plurality of wafers was subjected to the processing and the number of particles was measured with respect to each wafer. As a result, the number of particles significantly increased in comparison with the example 1, over an extensive range of 200 to 3000.

### Example 3

A resist was provided on a silicon substrate, and an opening was formed on the resist in a predetermined pattern. Then ion implantation was performed on the silicon substrate utilizing such resist as a mask. As was employed as the ion to be implanted. The resist employed was of a type used for a krypton fluoride (KrF) laser.

The silicon substrate was then placed on the apparatus according to the second embodiment shown in FIG. 4, at a position corresponding to the semiconductor substrate 106, and a mixed solution of sulfuric acid and hydrogen peroxide (SPM) was supplied for stripping the resist. The heater was only provided for the mixing unit 114.

When cleaning the substrate thus prepared, two factors namely (i) ion implantation density on the resist and (ii) SPM temperature were varied, and the resist removal performance was evaluated in each different case. The processing conditions were set as follows.

SPM composition: sulfuric acid/30wt % hydrogen peroxide=4/1 (in volume)

SPM injection amount on the wafer surface: 100 to 200 ml

SPM processing time: 2 minutes

Referring to the values in the Table, the SPM temperature was adjusted by the heater 116 provided for the mixing unit 114, taking into consideration the heat of mixing generated by the reaction of the sulfuric acid and the hydrogen peroxide. In the Table, the SPM temperature represents the temperature of the mixed solution in the mixing unit 114. In this example, the temperature inside the mixing unit 114 shown in Table 2 was adjusted by the heater 116.

The wafer defect inspector was employed for measurement of the number of particles that were stuck to the surface of the processed wafers. The results are shown in Table 2. The evaluation was made according to the following three grades.

∘: Particles were barely observed.

Δ: A small number of particles were observed.

×: A large number of particles were observed.

In view of the results shown in Table 2, it has been proven that when the temperature of the mixed solution is low, adequate removal efficiency cannot be achieved. Accordingly, it is understood that providing the heaters for the entire piping and also for the nozzle can effectively prevent the temperature of the mixed solution from falling during the delivery, thereby improving the removal efficiency.

Further, it has been proven that the variation in removal efficiency due to temperature is particularly prominent when the ion implantation density is relatively higher. It is, therefore, critical with respect to the specimens subjected to the ion implantation density of 1×10¹⁴ cm⁻² or more, to prevent the temperature drop of the mixed solution during the delivery, for example by providing the heater to the entire piping.

TABLE 2

| SPM temperature | Ion implantation density | | | |
|---|---|---|---|---|
| (Centigrade) | 5.00E+13 | 1.00E+14 | 5.00E+14 | 1.00E+15 |
| 70 | X | X | X | X |
| 80 | X | X | X | X |
| 90 | X | X | X | X |
| 100 | ◯ | Δ | X | X |
| 110 | ◯ | ◯ | Δ | X |
| 120 | ◯ | ◯ | ◯ | X |
| 130 | ◯ | ◯ | ◯ | X |
| 140 | ◯ | ◯ | ◯ | Δ |
| 150 | ◯ | ◯ | ◯ | ◯ |

### Example 4

A resist was provided on a silicon substrate, and an opening was formed on the resist in a predetermined pattern. Then ion implantation was performed on the silicon substrate utilizing such resist as a mask. As was employed as the ion to be implanted, and the implantation density was set at 5×10¹⁴cm⁻². The resist employed was of a type used for a krypton fluoride (KrF) laser.

The silicon substrate was then placed on the apparatus according to the first embodiment shown in FIG. 1, and a mixed solution of sulfuric acid and hydrogen peroxide (SPM) was supplied for stripping the resist. The heaters were provided for the nozzle 112, the entire piping 115 and the mixing unit 114. When cleaning the substrate thus prepared, the wafer rotation speed (i.e. SPM flow rate) was varied as No.1 and 2 of Table 3, the resist removal performance was evaluated in each case.

TABLE 3

| | |
|---|---|
| Rotation speed | |
| (SPM flow rate) | Processing time |

No. 1

| | | |
|---|---|---|
| Step 1 | 500 rpm (800 cc) | 15 seconds |
| Step 2 | 15 rpm (800 cc) | 5 seconds |
| Step 3 | 15 rpm (0 cc) | 20 seconds |

No. 2

| | | |
|---|---|---|
| Step 1 | 500 rpm (800 cc) | 15 seconds |
| Step 2 | 500 rpm (800 cc) | 5 seconds |
| Step 3 | 500 rpm (0 cc) | 20 seconds |

Also, specimens similarly prepared to the foregoing were subjected to the silicon substrate processing on the apparatus shown in FIG. 1, but without the mixing unit 114. In place of the mixing unit 114, following two nozzles were employed for injecting a chemical solution to the silicon substrate surface, for performing the resist stripping process. This corresponds to No.3 given below.

(i) a first nozzle that injects sulfuric acid to the silicon substrate

(ii) a second nozzle that injects hydrogen peroxide to the silicon substrate

The number of particles stuck to the wafer surface was measured in a similar manner to the foregoing examples, and the results are as follows (two wafers were evaluated in the respective cases).

| | |
|---|---|
| No. 1: | 15 pcs./wafer, 24 pcs./wafer |
| No. 2: | 3489 pcs./wafer, 1907 pcs./wafer |
| No. 3: | 30000+ pcs./wafer, 15874 pcs./wafer |

### Comparative Example 2

The example 4 employs the apparatus according to the first embodiment shown in FIG. 1, which includes the heater 116 provided for the mixing unit 114. In contrast in this comparative example, the apparatus as shown in FIG. 1 but without the heater 116 was employed. With such apparatus, the resist stripping process was performed at the rotation speed according to No.1 above. The number of particles stuck to the surface of two wafers was measured in a similar manner to the foregoing examples, and as a result the number of particles proved to be over 30,000 pieces on all of the wafers.

### Example 5

Following two apparatuses were employed for performing the resist stripping process, and the processing performance was evaluated. The rotation speed of the wafer was similarly adjusted to that according to No.1 of the example 4.

Apparatus 1: the apparatus according to the first embodiment (FIG. 1), with a nozzle (injecting a chemical solution to a central portion of the wafer)

Apparatus 2: the apparatus according to the second embodiment (FIG. 4), with two nozzles (injecting the chemical solution to a central portion and peripheral portion of the wafer, respectively).

The ion implantation conditions were set as follows.

Ion type: As

Implantation density: 1×10¹⁵ cm⁻²

The number of particles stuck to the wafer surface was measured in a similar manner to the foregoing examples, and the results are as follows.

| | |
|---|---|
| Apparatus 1: | 273 pcs./wafer, 191 pcs./wafer |
| Apparatus 2: | 21 pcs./wafer, 13 pcs./wafer |

It has been proven that employing two nozzles prominently improves the removal efficiency when the ion dose rate is higher.

### Example 6

Following two apparatuses were employed for performing the resist stripping process, and the processing performance was evaluated. The rotation speed of the wafer was similarly adjusted to that according to No.1 of the example 4.

Apparatus 1: the apparatus according to the first embodiment (FIG. 1), with a nozzle heater

Apparatus 2: the apparatus according to the first embodiment (FIG. 1), without the nozzle heater

The ion implantation conditions were set as follows.

Ion type: As

Implantation density: 1×10¹⁵ cm⁻²

The number of particles stuck to the wafer surface was measured in a similar manner to the foregoing examples, and the results are as follows. The unit of the numeral values is pieces per wafer.

Apparatus 1:

| | |
|---|---|
| First wafer | 18 |
| Second wafer | 24 |
| Third wafer | 15 |
| Fourth wafer | 21 |

Apparatus 2:

| | |
|---|---|
| First wafer | 372 |
| Second wafer | 83 |
| Third wafer | 31 |
| Fourth wafer | 26 |

With the apparatus 2 without the nozzle heater, a tendency that the removal efficiency is degraded in an initial stage of the processing has been observed. This is presumably because the chemical solution retained at the tip portion of the nozzle becomes cool during the standby time before starting the processing.

It is apparent that the present invention is not limited to the above embodiment, that may be modified and changed without departing from the scope and spirit of the invention.

What is claimed is:

1. A substrate processing apparatus, comprising:
a substrate mounting table that rotates with a semiconductor substrate retained thereon;
a first container that stores a first liquid to be supplied to a surface of said semiconductor substrate;
a second container that stores a second liquid to be supplied to said surface of said semiconductor substrate;
a mixing unit connecting said first container and said second container, so as to mix said first liquid and said second liquid supplied from said first and said second containers thus to give a mixed solution;
a nozzle that supplies said mixed solution to said surface of said semiconductor substrate;
a piping connected to said mixing unit and to said nozzle, so as to conduct said mixed solution from said mixing unit to said nozzle; and
a piping heater that heats said piping.

2. The substrate processing apparatus according to claim 1, wherein said piping heater heats an entirety of said piping, from the connection point with said mixing unit to the connection point with said nozzle.

3. The substrate processing apparatus according to claim 1, further comprising a heater that heats said mixing unit.

4. The substrate processing apparatus according to claim 1, further comprising a nozzle heater that heats said nozzle.

5. The substrate processing apparatus according to claim 1, wherein said mixing unit is of a tightly closed structure.

6. The substrate processing apparatus according to claim 1, wherein said first liquid and said second liquid are caused to spirally move along an inner wall of said mixing unit, thus to be mixed inside said mixing unit.

7. The substrate processing apparatus according to claim 1, wherein said mixing unit includes a hollow spiral tube.

8. The substrate processing apparatus according to claim 7, comprising a tubular heater through which a heat medium passes, wherein said spiral tube is disposed inside said tubular heater.

9. The substrate processing apparatus according to claim 1, comprising a plurality of nozzles that communicates with said mixing unit.

10. The substrate processing apparatus according to claim 9, wherein said nozzles include a first nozzle that supplies said mixed solution to a central portion of said semiconductor substrate, and a second nozzle that supplies said mixed solution to a peripheral portion of said semiconductor substrate.

11. The substrate processing apparatus according to claim 9, further comprising a moving unit that moves at least one of said nozzles.

12. The substrate processing apparatus according to claim 1, further comprising a controller that controls a rotating speed of said substrate mounting table,
wherein said controller performs a first step of rotating said semiconductor substrate at a relatively higher speed, and a second step of rotating said semiconductor substrate at a relatively lower speed after said first step.

13. The substrate processing apparatus according to claim 1, wherein said first liquid contains sulfuric acid, and said second liquid contains hydrogen peroxide.
